(19) United States
(12) Patent Application Publication
(10) Pub. No.: US 2024/0329546 A1
(43) Pub. Date: Oct. 3, 2024

(54) LITHOGRAPHY SYSTEM, SUBSTRATE SAG COMPENSATOR, AND METHOD

(71) Applicant: ASML Netherlands B.V., Veldhoven (NL)

(72) Inventor: Marcus Adrianus VAN DE KERKHOF, Helmond (NL)

(73) Assignee: ASML Netherlands B.V., Veldhoven (NL)

(21) Appl. No.: 18/578,947

(22) PCT Filed: Jun. 28, 2022
(86) PCT No.: PCT/EP2022/067792

§ 371 Date: Jan. 12, 2024

Related U.S. Application Data
(60) Provisional application No. 63/221,129, filed on Jul. 13, 2021.

(51) Int. Cl. G03F 7/00

(52) U.S. Cl. CPC G03F 7/70783; G03F 7/70525; G03F 7/707; G03F 7/70758; G03F 7/7085

(57) ABSTRACT

A system includes a support table having one or more protrusions and a pressure device. The one or more protrusions contact and support a substrate such that the substrate is suspended with respect to the support table. Sagging of the substrate when supported by the support table is based on a material and/or dimensions of the substrate. The pressure adjusts a pressure on a side of the substrate such that the sagging is reduced.

### CROSS-REFERENCE TO RELATED APPLICATIONS

This application claims priority of U.S. Provisional Patent Application No. 63/221,129, which was filed on Jul. 13, 2021, and which is incorporated herein in its entirety by reference.

### FIELD

The present disclosure relates to support structures for thin substrates, for example, a substrate table and a pressure device for use in lithographic apparatuses and systems.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. A lithographic apparatus can include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

Another lithographic system is an interferometric lithographic system where there is no patterning device, but rather a light beam is split into two beams, and the two beams are caused to interfere at a target portion of the substrate through the use of a reflection system. The interference causes lines to be formed at the target portion of the substrate.

It is important to perform metrology at different stages of a lithographic process. For example, during lithographic operation, different processing steps may require different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus may use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters may include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Such optical scatterometers can be used to measure parameters, such as critical dimensions of developed photosensitive resist or overlay error (OV) between two layers formed in or on the patterned substrate. Properties of the substrate can be determined by comparing the properties of an illumination beam before and after the beam has been reflected or scattered by the substrate.

The lithographic and metrology processes described above typically rely on precisely machined substrate tables (e.g., having near-perfect flatness). In order to meet the sub-micron tolerance requirements of lithographic fabrication, it is important for a flatness of substrates (e.g., wafers and patterning devices) to be within tolerance margins. Patterning devices can be relatively thin (e.g., a thickness less than 4 mm, 2 mm, or 1 mm) compared to a span of its surface area (e.g., approximately 150 mm in diameter) and can warp when subjected to even a minor uneven force. The warping can adversely impact subsequent lithographic and metrology processes performed on the substrate.

### SUMMARY

Accordingly, it is desirable to develop devices and methods that can prevent substrates from bending while being supported on a substrate table.

In some embodiments, a system comprises a support table with one or more protrusions and a pressure device. The one or more protrusions are configured to contact and support a substrate such that the substrate is suspended with respect to the support table. Sagging of the substrate when supported by the support table can be caused by the material(s) and/or dimensions of the substrate. The pressure device is configured to adjust a pressure on a side of the substrate such that the sagging is reduced.

In some embodiments, a method to reduce sagging of a substrate supported by a support table having one or more protrusions comprises contacting the one or more protrusions of the support table so as to support the substrate. The sagging of the substrate when supported by the support table is based on a material and/or dimensions of the substrate. The method further comprises adjusting a pressure on a side of the substrate, using a pressure device, such that the sagging is reduced.

In some embodiments, a lithography system comprises an illumination system, a projection system, a support table comprising one or more protrusions, and a pressure device. The illumination system is configured to illuminate a pattern of a patterning device. The projection system is configured to project an image of the pattern onto a substrate. The one or more protrusions are configured to contact and support the patterning device such that the substrate is suspended with respect to the support table. Sagging of the patterning device when supported by the support table can be caused by the material(s) and/or dimensions of the patterning device. The pressure device is configured to adjust a pressure on a side of the patterning device such that the sagging is reduced.

Further features of the present disclosure, as well as the structure and operation of various embodiments, are described in detail below with reference to the accompanying drawings. It is noted that the present disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable a person skilled in the relevant art(s) to make and use embodiments described herein.

FIG. 1A shows a reflective lithographic apparatus, according to some embodiments.

FIG. 1B shows a transmissive lithographic apparatus, according to some embodiments.

FIG. 2 shows a reflective lithographic apparatus, according to some embodiments.

FIG. 3 shows a lithographic cell, according to some embodiments.

FIG. 4 shows a system for sagging compensation, according to some embodiments.

FIG. 5 shows a flowchart of method steps to reduce sagging of a substrate, according to some embodiments.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) are provided as examples. The scope of the present disclosure is not limited to the disclosed embodiment(s). Claimed features are defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” may be used herein indicates the value of a given quantity that can vary based on a particular technology. Based on the particular technology, the term “about” may indicate a value of a given quantity that varies within, for example, 10-30% of the value (e.g., +10%, +20%, or +30% of the value).

Embodiments of the disclosure can be implemented in hardware, firmware, software, or any combination thereof. Embodiments of the disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc. may.

Before describing such embodiments in more detail, however, it is instructive to present an example environment in which embodiments of the present disclosure can be implemented.

### Example Lithographic Systems

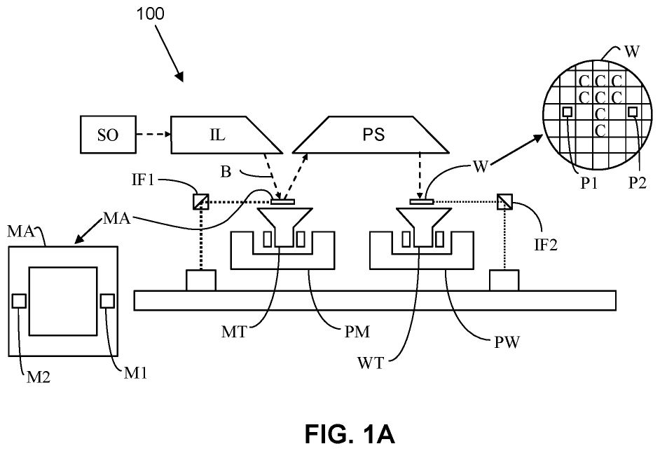

FIGS. 1A and 1B show schematic illustrations of a lithographic apparatus 100 and lithographic apparatus 100′, respectively, in which embodiments of the present disclosure can be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that may be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA can be transmissive (as in lithographic apparatus 100′ of FIG. 1B) or reflective (as in lithographic apparatus 100 of FIG. 1A). Transmission or reflection qualities may be chosen based on, for example, the use of EUV or DUV radiation. Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS may encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. The source SO and the illuminator IL, together with the beam delivery system BD, if required, can be referred to as a radiation system.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first- and higher-order diffracted beams (not shown). In some embodiments, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some embodiments, astigmatism aberration can be reduced by providing radiation poles (not shown) in opposite quadrants of the illumination system pupil IPU. Further, in some embodiments, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IF (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator only or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots should be calibrated for a smooth transfer of any payload (e.g., mask) to a fixed kinematic mount of a transfer station.

The lithographic apparatus 100 and 100′ can be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-)magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In a further embodiment, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

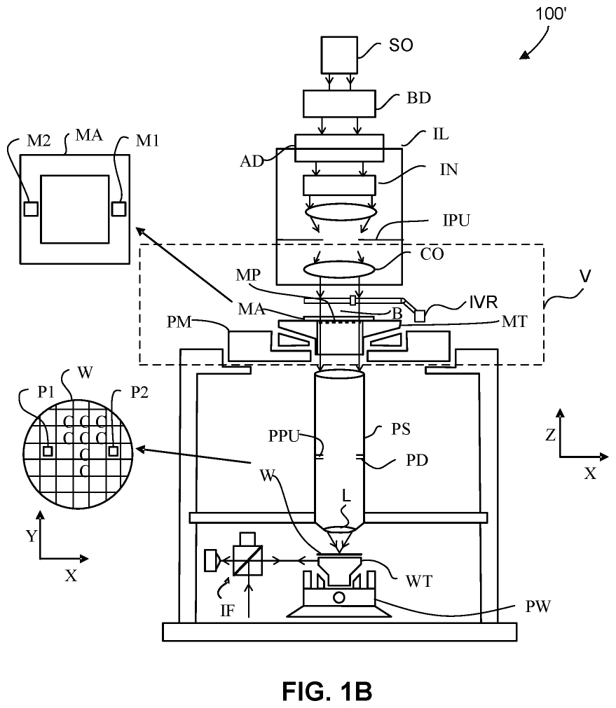

FIG. 2 shows the lithographic apparatus 100 in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 can be formed by a discharge produced plasma source. EUV radiation can be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li. Sn vapor, or any other suitable gas or vapor can be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap 230 (or contaminant barrier) further indicated herein at least includes a channel structure.

The collector chamber 212 can include a radiation collector CO, which can be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF. The virtual source point INTF is commonly referred to as the intermediate focus, and the source collector apparatus is arranged such that the intermediate focus INTF is located at or near an opening 219 in the enclosing structure 220. The virtual source point INTF is an image of the radiation emitting plasma 210. Grating spectral filter 240 is used in particular for suppressing infra-red (IR) radiation.

Subsequently the radiation traverses the illumination system IL, which can include a faceted field mirror device 222 and a faceted pupil mirror device 224 arranged to provide a desired angular distribution of beam of radiation 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination optics unit IL and projection system PS. The grating spectral filter 240 can optionally be present, depending upon the type of lithographic apparatus. Further, there can be more mirrors present than those shown in the FIG. 2, for example there can be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Exemplary Lithographic Cell

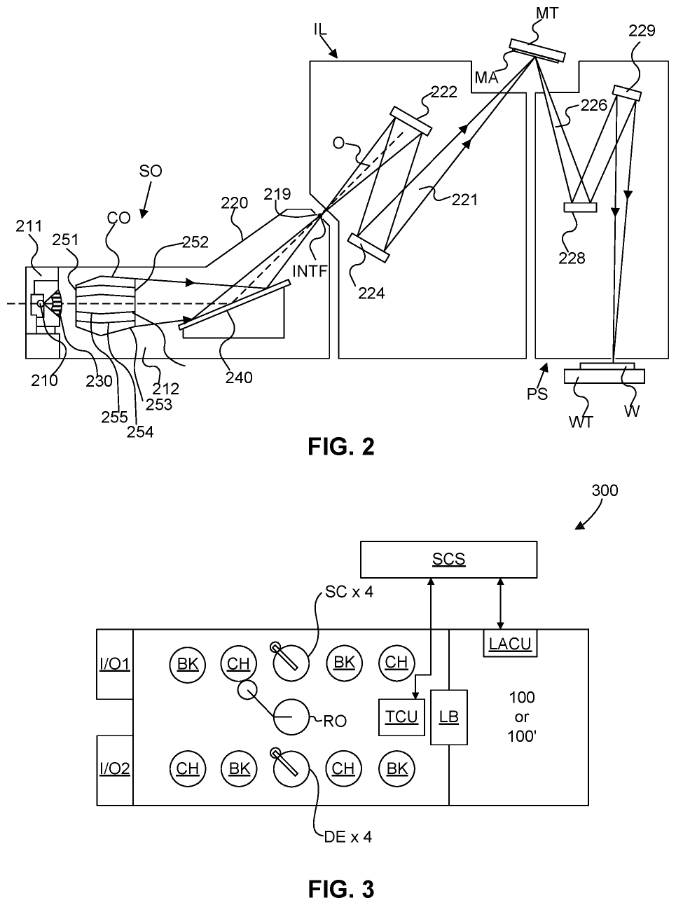

FIG. 3 shows a lithographic cell 300, also sometimes referred to a lithocell or cluster, according to some embodiments. Lithographic apparatus 100 or 100′ can form part of lithographic cell 300. Lithographic cell 300 can also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1. I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Exemplary Sagging Compensator for a Substrate Table

In the context of sagging compensation systems, it should be appreciated that the term “substrate” can be used herein to broadly refer to nominally flat planar structures that are supported by a support table (e.g., WT or MT (FIGS. 1A, 1B)). In this sense, the terms “patterning device,” “wafer,” “films,” or the like can be specific examples of a substrate. Depending on the hardness of a material and thickness (or lack thereof), a substrate can sag when the substrate is supported on a support table. For example, the support table can have smaller pedestals, or protrusions, that suspend the substrate above the body of the support table. Portions of the substrate that are not directly touching the protrusions can dip or sag (e.g., by the effects of gravity). The amount of sagging can be based on a material and/or dimensions of the substrate. The sagging can adversely impact the accuracy of lithography and metrology processes that rely on a flat substrate. The present disclosure provides structures and functions to address these problems. For example, a method uses a pressure differential to push the substrate against the sagging. The pressure difference can prevent sagging without having to rely on a solid structure to apply a force on the sagging substrate.

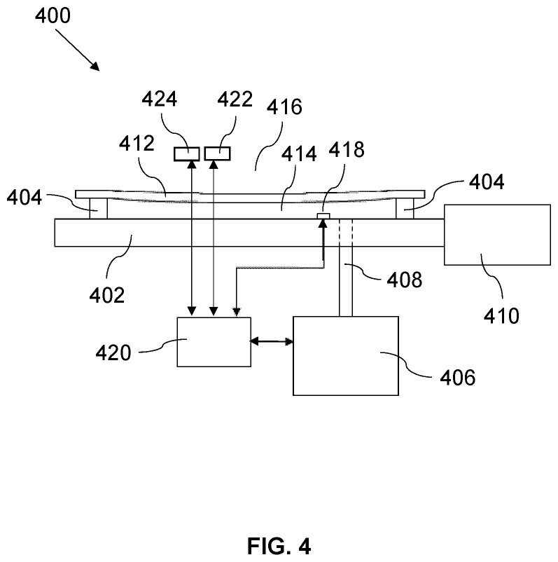

FIG. 4 shows a system 400, according to some embodiments. In some embodiments, system 400 can comprise a support table 402 and a pressure device 406. Support table 402 can comprise one or more protrusions 404. Pressure device 406 can comprise a conduit 408. Support table 402 can represent, for example, wafer table WT or mask table MT (FIG. 1). In some embodiments, protrusions 404 are disposed on a top side of support table 402. In the context of support tables, the terms “top,” “upper.” or the like can be used herein to describe a side of the support table that is to interact with a substrate 412. The opposite terms “bottom.” “lower,” or the like may be used for their reversed meanings.

In some embodiments, support table 402 can support substrate 412. However, large surface areas in contact increases the likelihood of contaminant exchange between two surfaces. It is sometimes desirable to reduce the amount of surface areas in contact to one another. For example, one or more protrusions 404 can come into contact with substrate 412 so as to suspend substrate 412 with respect to support table 402. That is, when substrate 412 is secured to support table 402 (e.g., via clamps (not shown)), a gap 414 is present between substrate 412 and a top surface of support table 402. Gap 414 can help alleviate contamination issues. Sagging of the substrate 412 can be made more severe if protrusions 404 are spaced far apart. A reason to space the protrusions far apart from one another may be to use a large area substrate 412 in transmission mode (protrusions spaced far apart so as not to obstruct the path of the transmitted beam). This provided example is non-limiting and a skilled artisan will appreciate that both reflective and transmissive substrates can implement embodiments described herein.

In some embodiments, it can be desirable to reduce a thickness of substrate 412 to improve optical qualities (e.g., better transmission) and/or to reduce mass of the patterning device (thereby reducing risk of slip during high accelerations in scanner). However, a lack of thickness can result in considerable sagging of substrate 412, particularly if a stiffness of substrate 412 is not enough to counter the forces exerted on substrate 412. Furthermore, in some instances, it can be desirable use a very thin substrate 412 such that substrate 412 can be called a film.

In some embodiments, a method to counter the sagging of substrate 412 can be to adjust a pressure on a side of substrate 412 such that sagging is reduced. The pressure can be adjusted using pressure device 406. In the context of substrates, it should be appreciated that the term “side” can be used to refer to a broad side of the substrate (i.e., a side with the largest planar surface area) while the terms “edge,” “periphery,” or the like can be used to refer to extremities of the substrate that encloses the broad side. For example, the circular surfaces of a disc substrate are the top and bottom sides of the substrate while the circumference of the circular side is the edge or periphery of the substrate.

In some embodiments, the pressure device 406 can be coupled to (e.g., in fluid communication with) the space at gap 414. In some embodiments, the conduit 408 can be coupled to the gap 414. The pressure device 406 can comprise, for example, a pump device that introduces or removes a pressurizing fluid (e.g., a gas) from gap 414. By adjusting a pressure at gap 414, a pressure differential is created between the two sides of substrate 412. For example, if substrate 412 sags in a downward direction on the page, the pressure in gap 414 can be made greater than the ambient pressure (e.g., P_{gap}>P_{ambient}) in space 416 on a side of substrate 412 that is opposite of gap 414. The pressure pushes upward on substrate 412 with a force to counter the sagging.

In some embodiments, pressure device 406 need not be limited to being coupled to gap 414. For example, pressure device 406 can be coupled to the space 416 (this configuration is not shown in FIG. 4). In this scenario, the ambient pressure can be adjusted so as to create the condition P_{gap}>P_{ambient} in order to prevent the sagging of substrate 412. In the context of sagging prevention, the term “prevent” or the like can be used to refer to full or partial reduction of sagging. For example, without pressure compensation, substrate 412 might sag approximately 5 microns. With pressure compensation, the sagging can be reduce to approximately 2 microns. Then, it can be said that approximately 3 microns of sagging was prevented using pressure device 406. It should be appreciated that embodiments described herein can reduce the sagging to approximately 2 microns or less, 1 micron or less, 0.5 microns less, or 0.1 microns or less.

In some embodiments, system 400 can comprise a pressure sensor 418 and a controller 420. Pressure sensor 418 can be disposed at gap 414. Pressure sensor 418 can measure a pressure at gap 414. Pressure sensor 418 can generate a measurement signal that comprises information about the pressure at gap 414. Controller 420 can receive the measurement signal from pressure sensor 418 to determine a pressure at gap 414. Based on the determined pressure, controller 420 can generate a control signal to control pressure device 406 to adjust a pressure at gap 414 and/or adjust an ambient pressure at space 416.

In some embodiments, system 400 can comprise a pressure sensor 422 in lieu of, or in addition to, pressure sensor 418. Pressure sensor 422 can be disposed at space 416 (i.e., exposed to ambience of system 400). Pressure sensor 422 is to space 416 as pressure sensor 418 is to gap 414. Controller 420 can determine a pressure difference between gap 414 and ambience by analyzing received measurement signals from pressure sensors 418 and 422. A control signal generated by controller 420 can be based on the measured difference in pressures above and below substrate 412.

In some embodiments, controller 420 can be programmed to have information about expected ambient conditions, material properties and dimensions of substrate 412, and/or any other information that influences sagging behavior of substrate 412. The control signal generated by controller 420 can be based on the programmed information about expected ambience conditions, material properties and dimensions of substrate 412, and/or any other information that influences sagging behavior of substrate 412—in lieu of or in addition to the data from the various sensors of system 400. When data from other sensors are unavailable, controller 420 can be said to operate in a forward-looking configuration (prediction based on preprogrammed information about system 400). When data from sensors is available, particularly in real-time, controller can be said to operate in a feedback configuration.

In some embodiments, system 400 can comprise an actuator 410. Actuator 410 can be coupled to support table 402. Actuator 410 can actuate (e.g., translate, rotate, or the like) support table 402 to move substrate 412 from one location to another. When in motion, a flow is observed at space 416 just above substrate 412. As a consequence of Bernoulli's principle, a pressure differential between gap 414 and space 416 can vary from the motion of substrate 412. In a lithographic apparatus, a mask table MT (FIG. 1) can undergo fast scanning operations, resulting in considerable pressure differentials above and below the substrate. Pressure device 406 can be used to compensate a pressure change resulting from the moving of substrate 412. Controller 420 can be programmed to take into account the amount of pressure differential that results from the moving of substrate 412. For example, controller 420 can be configured to estimate a pressure differential between gap 414 and space 416 based on equation 1:

$$\frac{ρ \cdot ( {( {v}_{space} - {v}_{r} )}^{2} - {( {v}_{gap} - {v}_{r} )}^{2} )}{2} ≅ \frac{ρ \cdot {( {v}_{space}^{2} - {v}_{gap} )}^{2}}{2} . \qquad Eq . 1$$

Here, ρ is the density of air (air is used as a non-limiting example), vᵣ is the reticle scan velocity, v_{space} is a flow velocity at space 416, and v_{gap} is the flow velocity at gap 414. When vᵣ increases, controller 420 can communicate with pressure device 406 via a control signal to compensate a pressure change resulting from the moving.

It should be appreciated, in some embodiments, that flow velocities in gap 414 and/or space 416 can be adjusted using pressure device 406. Pressure device 406 can comprise a vacuum pump and/or blower to generate gas flows in gap 414 and/or space 416. The adjusting of a pressure on a side of substrate 412 such that the sagging is reduced can be achieved by introducing/removing a pressurizing gas from gap 414 and/or space 416 such that flows are created. In one example, if v_{gap} and v_{space} are fast compared to vᵣ, then the motion of support table 402 can be rendered negligible, as shown by the approximation shown in equation 1. To reach this condition, in some embodiments, controller 420 can be used to generate a difference in velocities that is different by approximately a factor of 2, 5, 10, or greater.

In some embodiments, the control signal generated by controller 420 can be enhanced using additional sensors. For example, system 400 can comprise an optical sensor 424 to measure a feature on substrate 412. The feature can be structured such that a change can be measured by optical sensor 424 when substrate 412 sags. Optical sensor 424 can generate a measurement signal that is received by controller 420. Controller 420 can use the information from optical sensor 424 to modify the control signal to compensate for the sagging.

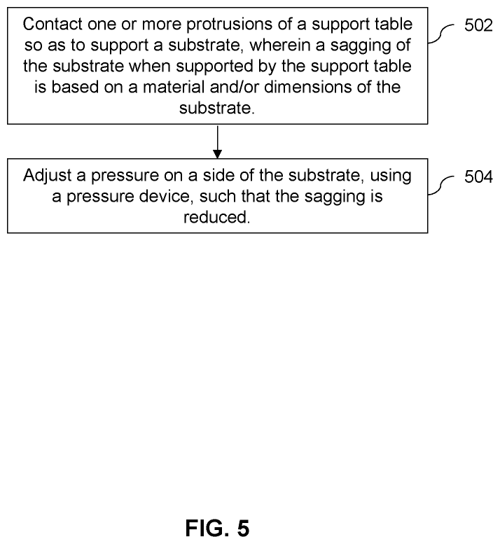

FIG. 5 shows method steps to reduce sagging of a substrate, according to some embodiments. System 400 (FIG. 4) can be used for the method steps. At step 502, one or more protrusions 404 are contacted to substrate 412. The sagging of substrate 412 when supported by support table 402 can be based on a material and/or dimensions of substrate 412. At step 504, a pressure is adjusted on a side of substrate 412, using pressure device 406, such that the sagging is reduced.

The method steps of FIG. 5 can be performed in any conceivable order and it is not required that all steps be performed. Moreover, the method steps of FIG. 5 described above merely reflect an example of steps and are not limiting. That is, further method steps and functions can be envisaged based upon embodiments described in reference to FIGS. 1-4.

The embodiments may further be described using the following clauses:
1. A system comprising:
   a support table comprising one or more protrusions configured to contact and support a substrate such that the substrate is suspended with respect to the support table, wherein a sagging of the substrate when supported by the support table is based on a material and/or dimensions of the substrate; and
   a pressure device configured to adjust a pressure on a side of the substrate such that the sagging is reduced.
2. The system of clause 1, wherein the pressure device comprises a conduit coupled to a gap between the substrate and the support table and the pressure device is further configured to introduce and/or remove a pressurizing gas from the gap to adjust the pressure on the side of the substrate.
3. The system of clause 1, wherein the pressure device is configured to generate a flow of pressurizing gas at the side of the substrate to adjust the pressure on the side of the substrate.
4. The system of clause 1, further comprising a controller configured to control the pressure device to adjust the pressure.
5. The system of clause 4, further comprising a pressure sensor configured to generate a measurement signal, wherein the controller is configured to receive the measurement signal and to determine the pressure based on the measurement signal.
6. The system of clause 5, wherein:
   the controller is further configured to generate a control signal based on the determined pressure; and
   the pressure device is further configured to receive the control signal and adjust the pressure based on the control signal.
7. The system of clause 6, wherein:
   the pressure sensor is disposed at a gap between the substrate and the support table;
   the system further comprises a second pressure sensor exposed to an ambience of the system and is configured to generate a second measurement signal;
   the controller is further configured to:
      receive the second measurement signal;
      determine a pressure difference between the gap and the ambience based on the measurement signal and the second measurement signal; and
   the generating the control signal is further based on the pressure difference.
8. The system of clause 1, wherein the pressure device is further configured to adjust the pressure at a gap between the suspended substrate and the support table.
9. The system of clause 1, wherein the pressure device is further configured to adjust an ambient pressure of the system.
10. The system of clause 1, further comprising an actuator configured to move the support table, wherein the pressure device is further configured to compensate a pressure change resulting from the moving.
11. The system of clause 10, further comprising a controller configured to control the pressure device to compensate the pressure change resulting from the moving.
12. A method to reduce sagging of a substrate supported by a support table comprising one or more protrusions, the method comprising:
   contacting the one or more protrusions of the support table so as to support the substrate, wherein the sagging of the substrate when supported by the support table is based on a material and/or dimensions of the substrate; and
   adjusting a pressure on a side of the substrate, using a pressure device, such that the sagging is reduced.
13. The method of clause 12, wherein the adjusting the pressure comprises supplying a flow of pressurizing gas at the side of the substrate using the pressure device.
14. The method of clause 12, further comprising determining a pressure at the side of the substrate using a pressure sensor, wherein the adjusting comprises:
   generating a control signal based on the determined pressure using a controller; and
   receiving the control signal at the pressure device to perform the adjusting.
15. The method of clause 14, wherein:
   information provided by the pressure sensor corresponds to a gap between the substrate and the support table;
   determining a pressure difference between the gap and an ambience of the support table using a second pressure sensor exposed to the ambience; and
   the generating the control signal is further based on the pressure difference.
16. The method of clause 12, further comprising moving the support table using an actuator, wherein the adjusting the pressure comprises compensating a pressure change resulting from the moving.
17. A lithography system comprising:
   an illumination system configured to illuminate a pattern of a patterning device;
   a projection system configured to project an image of the pattern onto a substrate; and
   a support table comprising one or more protrusions configured to contact and support the patterning device such that the patterning device is suspended with respect to the support table, wherein a sagging of the patterning device when supported by the support table is based on a material and/or dimensions of the patterning device; and
   a pressure device configured to adjust a pressure on a side of the substrate such that the sagging is reduced.
18. The lithography system of clause 17, wherein the pressure device is configured to generate a flow of pressurizing gas at the side of the substrate to adjust the pressure on the side of the substrate.
19. The lithography system of clause 17, further comprising:
   a controller configured to control the pressure device to adjust the pressure; and
   a pressure sensor configured to generate a measurement signal, wherein the controller is configured to receive the measurement signal and to determine the pressure based on the measurement signal and to generate a control signal based on the determined pressure; and
   the pressure device is further configured to receive the control signal and adjust the pressure based on the control signal.
20. The lithography system of clause 17, further comprising:
   an actuator configured to move the support table, wherein the pressure device is further configured to compensate a pressure change resulting from the moving; and
   a controller configured to control the pressure device to compensate the pressure change resulting from the moving.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, use of the term “die” herein may be considered as being specific examples of the more general terms “target portion”. A substrate referred to herein may be processed, before or after exposure, in for example a track unit (a tool that typically applies a layer of resist to a substrate and develops the exposed resist), a metrology unit and/or an inspection unit. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of disclosed embodiments in the context of optical lithography, it will be appreciated that the disclosed embodiments may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

The above examples are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

While specific embodiments of the disclosure have been described above, it will be appreciated that embodiments of the present disclosure may be practiced otherwise than as described. The descriptions are intended to be illustrative, not limiting. Thus it will be apparent to one skilled in the art that modifications may be made to the disclosure as described without departing from the scope of the claims set out below.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of the protected subject matter should not be limited by any of the above-described exemplary embodiments, but should be defined only in accordance with the following claims and their equivalents.

1. A system comprising:
a support table comprising one or more protrusions configured to contact and support a substrate such that the substrate is suspended with respect to the support table, wherein a sagging of the substrate when supported by the support table is based on a material and/or dimensions of the substrate; and
a pressure device configured to adjust a pressure on a side of the substrate such that the sagging is reduced.

2. The system of claim 1, wherein:
the pressure device comprises a conduit coupled to a gap between the substrate and the support table and the pressure device is further configured to introduce and/or remove a pressurizing gas from the gap to adjust the pressure on the side of the substrate; and
the pressure device is configured to generate a flow of pressurizing gas at the side of the substrate to adjust the pressure on the side of the substrate.

3. The system of claim 1, further comprising:
a controller configured to control the pressure device to adjust the pressure; and
a pressure sensor configured to generate a measurement signal, wherein the controller is configured to receive the measurement signal and to determine the pressure based on the measurement signal, wherein:
the controller is further configured to generate a control signal based on the determined pressure; and
the pressure device is further configured to receive the control signal and adjust the pressure based on the control signal.

4. The system of claim 3, wherein:
the pressure sensor is disposed at a gap between the substrate and the support table;
the system further comprises a second pressure sensor exposed to an ambience of the system and is configured to generate a second measurement signal;
the controller is further configured to:
receive the second measurement signal;
determine a pressure difference between the gap and the ambience based on the measurement signal and the second measurement signal; and
the generating the control signal is further based on the pressure difference.

5. The system of claim 1, wherein:
the pressure device is further configured to adjust the pressure at a gap between the suspended substrate and the support table; and
the pressure device is further configured to adjust an ambient pressure of the system.

6. The system of claim 1, further comprising:
an actuator configured to move the support table, wherein the pressure device is further configured to compensate a pressure change resulting from the moving; and
a controller configured to control the pressure device to compensate the pressure change resulting from the moving.

7. A method to reduce sagging of a substrate supported by a support table comprising one or more protrusions, the method comprising:
contacting the one or more protrusions of the support table so as to support the substrate, wherein the sagging of the substrate when supported by the support table is based on a material and/or dimensions of the substrate; and
adjusting a pressure on a side of the substrate, using a pressure device, such that the sagging is reduced.

8. The method of claim 7, wherein the adjusting the pressure comprises supplying a flow of pressurizing gas at the side of the substrate using the pressure device.

9. The method of claim 7, further comprising determining a pressure at the side of the substrate using a pressure sensor, wherein the adjusting comprises:
generating a control signal based on the determined pressure using a controller; and
receiving the control signal at the pressure device to perform the adjusting.

10. The method of claim 9, wherein:
information provided by the pressure sensor corresponds to a gap between the substrate and the support table;
determining a pressure difference between the gap and an ambience of the support table using a second pressure sensor exposed to the ambience; and
the generating the control signal is further based on the pressure difference.

11. The method of claim 7, further comprising moving the support table using an actuator, wherein the adjusting the pressure comprises compensating a pressure change resulting from the moving.

12. A lithography system comprising:
an illumination system configured to illuminate a pattern of a patterning device;
a projection system configured to project an image of the pattern onto a substrate; and
a support table comprising one or more protrusions configured to contact and support the patterning device such that the patterning device is suspended with respect to the support table, wherein a sagging of the patterning device when supported by the support table is based on a material and/or dimensions of the patterning device; and
a pressure device configured to adjust a pressure on a side of the substrate such that the sagging is reduced.

13. The lithography system of claim 12, wherein the pressure device is configured to generate a flow of pressurizing gas at the side of the substrate to adjust the pressure on the side of the substrate.

14. The lithography system of claim 12, further comprising:
a controller configured to control the pressure device to adjust the pressure; and
a pressure sensor configured to generate a measurement signal, wherein the controller is configured to receive the measurement signal and to determine the pressure based on the measurement signal and to generate a control signal based on the determined pressure; and
the pressure device is further configured to receive the control signal and adjust the pressure based on the control signal.

15. The lithography system of claim 12, further comprising:
an actuator configured to move the support table, wherein the pressure device is further configured to compensate a pressure change resulting from the moving; and
a controller configured to control the pressure device to compensate the pressure change resulting from the moving.
